(19) United States
(12) Patent Application Publication
(10) Pub. No.: US 2025/0393280 A1
(43) Pub. Date: Dec. 25, 2025

(54) SYSTEM AND METHOD FOR DETECTING PARTICLES WITH A DETECTOR DURING INSPECTION

(71) Applicant: ASML Netherlands B.V., Veldhoven (NL)

(72) Inventors: Eunseong MOON, San Jose, CA (US); Yongxin WANG, San Ramon, CA (US); Rui-Ling LAI, Toufen city (TW); Farhang VESSAL, San Jose, CA (US); Chongyang LENG, Milpitas (CN)

(73) Assignee: ASML Netherlands B.V., Veldhoven (NL)

(21) Appl. No.: 18/878,862

(22) PCT Filed: Aug. 1, 2023
(86) PCT No.: PCT/EP2023/071272

§ 371 Date: Dec. 24, 2024

Related U.S. Application Data
(60) Provisional application No. 63/403,534, filed on Sep. 2, 2022.

(51) Int. Cl. H10D 64/23; H10D 8/01; H10D 8/50; H10D 62/60; H10D 62/83

(52) U.S. Cl. CPC H10D 64/23; H10D 8/01; H10D 8/50; H10D 62/60; H10D 62/83

(57) ABSTRACT

Systems, apparatuses, and methods include a detector including a detection element including a portion of a silicon substrate comprising: a front side of the portion of the silicon substrate including a PIN diode that comprises a p-type region and an n-type region; a back side of the portion of the silicon substrate, opposite of the front side, comprising a substantially uniform surface; and a layer on the back side of the portion of the silicon substrate; wherein: a region between the p-type region and the n-type region is configured to form a depletion region when a reverse bias is applied between the p-type region and the n-type region, and the PIN diode is configured to detect an electron that enters the back side of the portion of the silicon substrate and passes through the portion of the silicon substrate to the depletion region.

### CROSS-REFERENCE TO RELATED APPLICATIONS

This application claims priority of U.S. application 63/403,534 which was filed on Sep. 2, 2022 and which is incorporated herein in its entirety by reference.

### FIELD

The description herein relates to the field of inspection systems, and more particularly to systems for detecting particles with a detector during inspection.

### BACKGROUND

In manufacturing processes of integrated circuits (ICs), unfinished or finished circuit components are inspected to ensure that they are manufactured according to design and are free of defects. An inspection system utilizing an optical microscope typically has resolution down to a few hundred nanometers; and the resolution is limited by the wavelength of light. As the physical sizes of IC components continue to reduce down to sub-100 or even sub-10 nanometers, inspection systems capable of higher resolution than those utilizing optical microscopes are needed.

A charged particle (e.g., electron) beam microscope, such as a scanning electron microscope (SEM) or a transmission electron microscope (TEM), capable of resolution down to less than a nanometer, serves as a practicable tool for inspecting IC components having a feature size that is sub-100 nanometers. With a SEM, electrons of a single primary electron beam, or electrons of a plurality of primary electron beams, can be focused at locations of interest of a wafer under inspection. The primary electrons interact with the wafer and may be backscattered or may cause the wafer to emit secondary electrons. The intensity of the electron beams comprising the backscattered electrons and the secondary electrons may vary based on the properties of the internal and external structures of the wafer, and thereby may indicate whether the wafer has defects.

### SUMMARY

Embodiments of the present disclosure provide apparatuses, systems, and methods for detecting particles with a detector. In some embodiments, systems and methods may include a silicon substrate thinned to a thickness of 30 μm or less; a front side of the silicon substrate including a lateral PIN diode formed by a p-type implant and an n-type implant; a region between the p-type implant and the n-type implant configured to form a depletion region when a reverse bias is applied between the p-type implant and the n-type implant; a back side of the silicon substrate, opposite of the front side, comprising a substantially uniform surface; and a protective layer on the substantially uniform surface on the back side of the silicon substrate, wherein the lateral PIN diode is configured to detect an electron that enters the back side of the silicon substrate and passes through the silicon substrate to the depletion region.

In some embodiments, a detector may include a plurality of detection elements, a detection element of the plurality of detection elements comprising: a portion of a silicon substrate comprising: a front side of the portion of the silicon substrate including a PIN diode that comprises a p-type region and an n-type region; a back side of the portion of the silicon substrate, opposite of the front side, comprising a substantially uniform surface; and a layer on the back side of the portion of the silicon substrate; wherein: a region between the p-type region and the n-type region is configured to form a depletion region when a reverse bias is applied between the p-type region and the n-type region, and the PIN diode is configured to detect an electron that enters the back side of the portion of the silicon substrate and passes through the portion of the silicon substrate to the depletion region.

In some embodiments, a detector may include a plurality of detection elements, a detection element of the plurality of detection elements comprising: a portion of a silicon substrate comprising: a front side of the portion of the substrate including a PIN diode that comprises a p-type region and an n-type region; a back side of the portion of the substrate, opposite of the front side, comprising a substantially uniform surface; and a layer on the back side of the portion of the substrate; wherein: a region between the p-type region and the n-type region is configured to form a depletion region when a reverse bias is applied between the p-type region and the n-type region, and the PIN diode is configured to receive an electron incident on the back side of the portion of the substrate.

In some embodiments, a detector may include a plurality of detection elements, a detection element of the plurality of detection elements comprising: a portion of a substrate comprising: a front side of the portion of the substrate including a p-type region and an n-type region, the p-type region and the n-type region forming a PIN diode; and a back side of the portion of the substrate, opposite of the front side, comprising a substantially uniform surface; wherein: a region between the p-type region and the n-type region is configured to form a depletion region when a reverse bias is applied between the p-type region and the n-type region, and the PIN diode is configured to receive an electron passing from the back side of the portion of the substrate through the portion of the substrate.

In some embodiments, a method of forming a detection element of a detector may include forming a PIN diode on a front side of a silicon substrate by implanting, in the silicon substrate, p-type dopants to form a p-type region and n-type dopants to form an n-type region, wherein a region between the p-type region and the n-type region is configured to form a depletion region when a reverse bias is applied between the p-type region and the n-type region; thinning a back side of the silicon substrate, opposite of the front side, wherein the back side comprises a substantially uniform surface; and forming a layer on the back side of the silicon substrate, wherein the PIN diode is configured to detect an electron that enters the back side of the silicon substrate and passes through the silicon substrate to the depletion region.

### BRIEF DESCRIPTION OF THE DRAWINGS

FIG. 1 is a schematic diagram illustrating an exemplary electron beam inspection (EBI) system, consistent with embodiments of the present disclosure.

FIG. 2A is a schematic diagram illustrating an exemplary multi-beam system that is part of the exemplary charged particle beam inspection system of FIG. 1, consistent with embodiments of the present disclosure.

FIG. 2B is a schematic diagram illustrating an exemplary single-beam system that is part of the exemplary charged particle beam inspection system of FIG. 1, consistent with embodiments of the present disclosure.

FIG. 3A is a schematic representation of an exemplary structure of a detector, consistent with embodiments of the present disclosure.

FIG. 3B is a schematic illustration of a cross-sectional structure of a substrate of a detector, consistent with embodiments of the present disclosure.

FIG. 3C is a schematic illustration of a cross-sectional structure of a substrate of a detector, consistent with embodiments of the present disclosure.

FIG. 3D is a schematic illustration of an individual detection element, consistent with embodiments of the present disclosure.

FIG. 4 is a schematic illustration of an individual detection element, consistent with embodiments of the present disclosure.

FIG. 5 is a schematic illustration of an individual detection element, consistent with embodiments of the present disclosure.

FIGS. 6A, 6B, and 6C are schematic illustrations of metal geometries of individual detection elements, consistent with embodiments of the present disclosure.

FIG. 7 is a schematic illustration of a detector, consistent with embodiments of the present disclosure.

FIGS. 8A and 8B are flowcharts illustrating exemplary processes of forming a detection element, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing electron beams, the disclosure is not so limited. Other types of charged particle beams may be similarly applied. Furthermore, other imaging systems may be used, such as optical imaging, photodetection, x-ray detection, extreme ultraviolet inspection, deep ultraviolet inspection, or the like, in which they generate corresponding types of images.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional integrated circuits. One way to monitor the process is to inspect the chip circuit structures at various stages of their formation. Inspection may be carried out using a scanning electron microscope (SEM). A SEM can be used to image these extremely small structures, in effect, taking a “picture” of the structures of the wafer. The image can be used to determine if the structure was formed properly and also if it was formed at the proper location. If the structure is defective, then the process can be adjusted so the defect is less likely to recur. Defects may be generated during various stages of semiconductor processing. For the reason stated above, it is important to find defects accurately and efficiently as early as possible.

The working principle of a SEM is similar to a camera. A camera takes a picture by receiving and recording brightness and colors of light reflected or emitted from people or objects. A SEM takes a “picture” by receiving and recording energies or quantities of electrons reflected or emitted from the structures. Before taking such a “picture,” an electron beam may be provided onto the structures, and when the electrons are reflected or emitted (“exiting”) from the structures, a detector of the SEM may receive and record the energies or quantities of those electrons to generate an image. To take such a “picture,” some SEMs use a single electron beam (referred to as a “single-beam SEM”), while some SEMs use multiple electron beams (referred to as a “multi-beam SEM”) to take multiple “pictures” of the wafer. By using multiple electron beams, the SEM may provide more electron beams onto the structures for obtaining these multiple “pictures,” resulting in more electrons exiting from the structures. Accordingly, the detector may receive more exiting electrons simultaneously, and generate images of the structures of the wafer with a higher efficiency and a faster speed.

For example, typical detectors may be pixelated (e.g., including a plurality of detection elements) such that each detection element may receive a particle (e.g., photons, charged particles such as electrons, protons, etc.) projected from a sample and output a detection signal. Detection signals can be used to reconstruct images of sample structures under inspection and may be used, for example, to reveal defects in the sample.

Typical detection systems, however, suffer from constraints. Typical inspection systems may include a detection element with a lateral or vertical PIN diode on a substrate that detects particles by front side illumination. That is, the detection element detects particles by receiving particles on the front side of the detection element through the PIN diode, rather than on the back side of the detection element through the substrate. Detection elements that detect particles, especially low energy particles (e.g., electrons at less than 5 keV), by front side illumination exhibit low responsivity and low response speed due to carrier losses in the front side of the PIN diode. For example, carrier losses may occur due to a surface protection layer, heavily doped regions, surface metal layers, or electrical contacts on the front side of the PIN diode, among others. For example, carrier losses may occur due to surface metal layers or electrical contacts on the front side of the PIN diode absorbing some electrons. Detection elements with vertical PIN diodes also suffer constraints, such as the need to incorporate complicated through-substrate vias to integrate the PIN diode to a readout integrated circuit.

Moreover, detection element substrates are typically too thick to feasibly detect particles through back side illumination. While detection elements with a pure boron layer may achieve higher responsivity with either front side illumination or back side illumination, these detection elements operate with a low response speed for low energy particles due to the high sheet resistance of a thin junction layer.

Some of the disclosed embodiments provide systems and methods that address some or all of these disadvantages by providing a detector with detection elements that include a lateral PIN diode on a thin substrate and use back side illumination. The disclosed embodiments may include providing a silicon substrate with a PIN diode on a front side of the substrate; a back side of the silicon substrate including a substantially uniform surface (e.g., a surface without implanted dopants, a material with an implanted dopant concentration of zero, zero PIN diodes, zero cathodes, zero anodes, etc.); a protective layer on the back side of the silicon substrate; and where the PIN diode is configured to detect an electron that enters the back side of the silicon substrate and passes through the silicon substrate to a depletion region of the PIN diode, thereby increasing the detection response speed, responsivity, and fill factor with an acceptable level of parasitic capacitance and that is easily integrated with readout integrated circuits.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Without limiting the scope of the present disclosure, some embodiments may be described in the context of providing detectors and detection methods in systems utilizing electron beams. However, the disclosure is not so limited. Other types of charged particle beams may be similarly applied. Furthermore, systems and methods for detection may be used in other imaging systems, such as optical imaging, photon detection, x-ray detection, ion detection, etc.

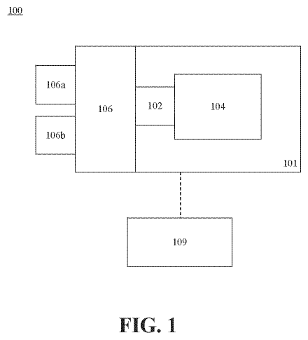

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system.

A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

Embodiments of this disclosure may provide a single charged-particle beam imaging system (“single-beam system”). Compared with a single-beam system, a multiple charged-particle beam imaging system (“multi-beam system”) may be designed to optimize throughput for different scan modes. Embodiments of this disclosure provide a multi-beam system with the capability of optimizing throughput for different scan modes by using beam arrays with different geometries and adapting to different throughputs and resolution requirements.

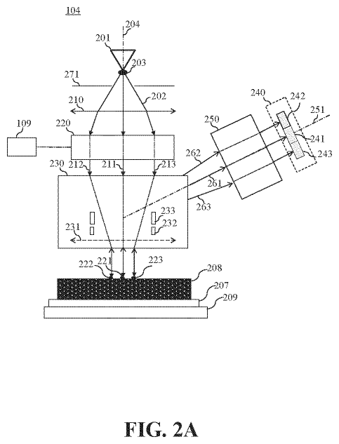

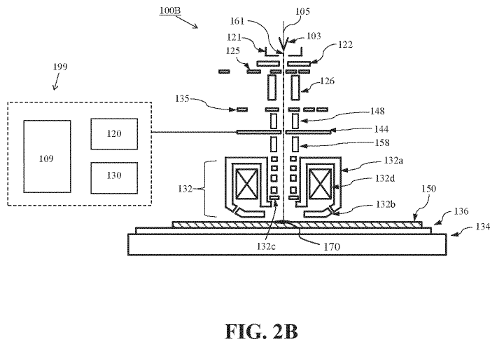

Reference is now made to FIG. 2A, which is a schematic diagram illustrating an exemplary electron beam tool 104 including a multi-beam inspection tool that is part of the EBI system 100 of FIG. 1, consistent with embodiments of the present disclosure. In some embodiments, electron beam tool 104 may be operated as a single-beam inspection tool that is part of EBI system 100 of FIG. 1. Multi-beam electron beam tool 104 (also referred to herein as apparatus 104) comprises an electron source 201, a Coulomb aperture plate (or “gun aperture plate”) 271, a condenser lens 210, a source conversion unit 220, a primary projection system 230, a motorized stage 209, and a sample holder 207 supported by motorized stage 209 to hold a sample 208 (e.g., a wafer or a photomask) to be inspected. Multi-beam electron beam tool 104 may further comprise a secondary projection system 250 and an electron detection device 240. Primary projection system 230 may comprise an objective lens 231. Electron detection device 240 may comprise a plurality of detection elements 241, 242, and 243. A beam separator 233 and a deflection scanning unit 232 may be positioned inside primary projection system 230.

Electron source 201, Coulomb aperture plate 271, condenser lens 210, source conversion unit 220, beam separator 233, deflection scanning unit 232, and primary projection system 230 may be aligned with a primary optical axis 204 of apparatus 104. Secondary projection system 250 and electron detection device 240 may be aligned with a secondary optical axis 251 of apparatus 104.

Electron source 201 may comprise a cathode (not shown) and an extractor or anode (not shown), in which, during operation, electron source 201 is configured to emit primary electrons from the cathode and the primary electrons are extracted or accelerated by the extractor and/or the anode to form a primary electron beam 202 that form a primary beam crossover (virtual or real) 203. Primary electron beam 202 may be visualized as being emitted from primary beam crossover 203.

Source conversion unit 220 may comprise an image-forming element array (not shown), an aberration compensator array (not shown), a beam-limit aperture array (not shown), and a pre-bending micro-deflector array (not shown). In some embodiments, the pre-bending micro-deflector array deflects a plurality of primary beamlets 211, 212, 213 of primary electron beam 202 to normally enter the beam-limit aperture array, the image-forming element array, and an aberration compensator array. In some embodiments, apparatus 104 may be operated as a single-beam system such that a single primary beamlet is generated. In some embodiments, condenser lens 210 is designed to focus primary electron beam 202 to become a parallel beam and be normally incident onto source conversion unit 220. The image-forming element array may comprise a plurality of micro-deflectors or micro-lenses to influence the plurality of primary beamlets 211, 212, 213 of primary electron beam 202 and to form a plurality of parallel images (virtual or real) of primary beam crossover 203, one for each of the primary beamlets 211, 212, and 213. In some embodiments, the aberration compensator array may comprise a field curvature compensator array (not shown) and an astigmatism compensator array (not shown). The field curvature compensator array may comprise a plurality of micro-lenses to compensate field curvature aberrations of the primary beamlets 211, 212, and 213. The astigmatism compensator array may comprise a plurality of micro-stigmators to compensate astigmatism aberrations of the primary beamlets 211, 212, and 213. The beam-limit aperture array may be configured to limit diameters of individual primary beamlets 211, 212, and 213. FIG. 2A shows three primary beamlets 211, 212, and 213 as an example, and it is appreciated that source conversion unit 220 may be configured to form any number of primary beamlets. Controller 109 may be connected to various parts of EBI system 100 of FIG. 1, such as source conversion unit 220, electron detection device 240, primary projection system 230, or motorized stage 209. In some embodiments, as explained in further details below, controller 109 may perform various image and signal processing functions. Controller 109 may also generate various control signals to govern operations of the charged particle beam inspection system.

Condenser lens 210 is configured to focus primary electron beam 202. Condenser lens 210 may further be configured to adjust electric currents of primary beamlets 211, 212, and 213 downstream of source conversion unit 220 by varying the focusing power of condenser lens 210. Alternatively, the electric currents may be changed by altering the radial sizes of beam-limit apertures within the beam-limit aperture array corresponding to the individual primary beamlets. The electric currents may be changed by both altering the radial sizes of beam-limit apertures and the focusing power of condenser lens 210. Condenser lens 210 may be an adjustable condenser lens that may be configured so that the position of its first principle plane is movable. The adjustable condenser lens may be configured to be magnetic, which may result in off-axis beamlets 212 and 213 illuminating source conversion unit 220 with rotation angles. The rotation angles change with the focusing power or the position of the first principal plane of the adjustable condenser lens. Condenser lens 210 may be an anti-rotation condenser lens that may be configured to keep the rotation angles unchanged while the focusing power of condenser lens 210 is changed. In some embodiments, condenser lens 210 may be an adjustable anti-rotation condenser lens, in which the rotation angles do not change when its focusing power and the position of its first principal plane are varied.

Objective lens 231 may be configured to focus beamlets 211, 212, and 213 onto a sample 208 for inspection and may form, in the current embodiments, three probe spots 221, 222, and 223 on the surface of sample 208. Coulomb aperture plate 271, in operation, is configured to block off peripheral electrons of primary electron beam 202 to reduce Coulomb effect. The Coulomb effect may enlarge the size of each of probe spots 221, 222, and 223 of primary beamlets 211, 212, 213, and therefore deteriorate inspection resolution.

Beam separator 233 may, for example, be a Wien filter comprising an electrostatic deflector generating an electrostatic dipole field and a magnetic dipole field (not shown in FIG. 2A). In operation, beam separator 233 may be configured to exert an electrostatic force by electrostatic dipole field on individual electrons of primary beamlets 211, 212, and 213. The electrostatic force is equal in magnitude but opposite in direction to the magnetic force exerted by magnetic dipole field of beam separator 233 on the individual electrons. Primary beamlets 211, 212, and 213 may therefore pass at least substantially straight through beam separator 233 with at least substantially zero deflection angles.

Deflection scanning unit 232, in operation, is configured to deflect primary beamlets 211, 212, and 213 to scan probe spots 221, 222, and 223 across individual scanning areas in a section of the surface of sample 208. In response to incidence of primary beamlets 211, 212, and 213 or probe spots 221, 222, and 223 on sample 208, electrons emerge from sample 208 and generate three secondary electron beams 261, 262, and 263. Each of secondary electron beams 261, 262, and 263 typically comprise secondary electrons (having electron energy ≤50 eV) and backscattered electrons (having electron energy between 50 eV and the landing energy of primary beamlets 211, 212, and 213). Beam separator 233 is configured to deflect secondary electron beams 261, 262, and 263 towards secondary projection system 250. Secondary projection system 250 subsequently focuses secondary electron beams 261, 262, and 263 onto detection elements 241, 242, and 243 of electron detection device 240. Detection elements 241, 242, and 243 are arranged to detect corresponding secondary electron beams 261, 262, and 263 and generate corresponding signals which are sent to controller 109 or a signal processing system (not shown), e.g., to construct images of the corresponding scanned areas of sample 208.

In some embodiments, detection elements 241, 242, and 243 detect corresponding secondary electron beams 261, 262, and 263, respectively, and generate corresponding intensity signal outputs (not shown) to an image processing system (e.g., controller 109). In some embodiments, each detection element 241, 242, and 243 may comprise one or more pixels. The intensity signal output of a detection element may be a sum of signals generated by all the pixels within the detection element.

In some embodiments, controller 109 may comprise image processing system that includes an image acquirer (not shown), a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detection device 240 of apparatus 104 through a medium such as an electrical conductor, optical fiber cable, portable storage media, IR, Bluetooth, internet, wireless network, wireless radio, among others, or a combination thereof. In some embodiments, the image acquirer may receive a signal from electron detection device 240 and may construct an image. The image acquirer may thus acquire images of sample 208. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, the image acquirer may acquire one or more images of a sample based on an imaging signal received from electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time sequence. The multiple images may be stored in the storage. In some embodiments, controller 109 may be configured to perform image processing steps with the multiple images of the same location of sample 208.

In some embodiments, controller 109 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213 incident on the wafer surface, can be used to reconstruct images of the wafer structures under inspection. The reconstructed images can be used to reveal various features of the internal or external structures of sample 208, and thereby can be used to reveal any defects that may exist in the wafer.

In some embodiments, controller 109 may control motorized stage 209 to move sample 208 during inspection of sample 208. In some embodiments, controller 109 may enable motorized stage 209 to move sample 208 in a direction continuously at a constant speed. In other embodiments, controller 109 may enable motorized stage 209 to change the speed of the movement of sample 208 over time depending on the steps of scanning process.

Although FIG. 2A shows that apparatus 104 uses three primary electron beams, it is appreciated that apparatus 104 may use one, two, or more number of primary electron beams. The present disclosure does not limit the number of primary electron beams used in apparatus 104. In some embodiments, apparatus 104 may be a SEM used for lithography. In some embodiments, electron beam tool 104 may be a single-beam system or a multi-beam system.

For example, as shown in FIG. 2B, an electron beam tool 100B (also referred to herein as apparatus 100B) may be a single-beam inspection tool that is used in EBI system 10, consistent with embodiments of the present disclosure. Apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In an imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered primary particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

FIG. 2B illustrates a charged particle beam apparatus in which an inspection system may use a single primary beam that may be configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150.

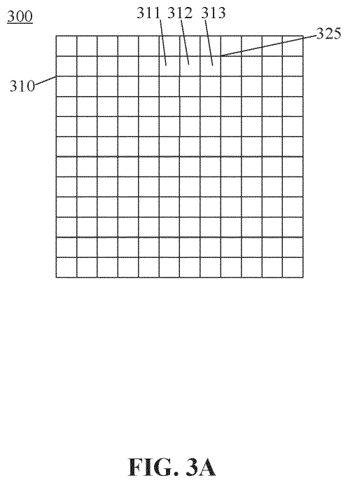

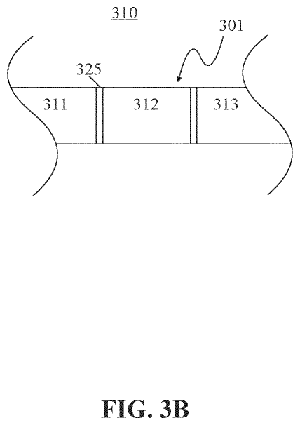

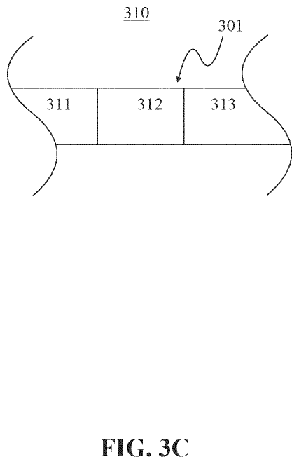

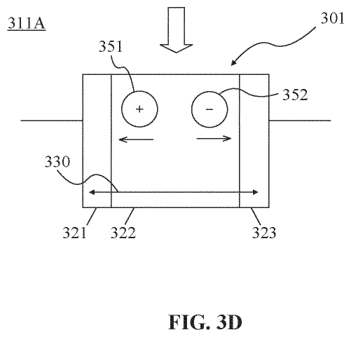

Reference is now made to FIG. 3A, which illustrates a schematic representation of an exemplary structure of a detector 300, consistent with embodiments of the present disclosure. Detector 300 may be provided as detector 144 or electron detection device 240 with reference to FIG. 2A and FIG. 2B. While one array is shown in FIG. 3A, it is appreciated that detector 300 may include multiple arrays, such as one array for each secondary electron beam.

Detector 300 may comprise an array of detection elements, including detection elements 311, 312, and 313. The detection elements may be arranged in a planar, two-dimensional array, the plane of the array being substantially perpendicular to an incidence direction of incoming charged particles. In some embodiments, detector 300 may be arranged so as to be inclined relative to the incidence direction.

Detector 300 may comprise a substrate 310. Substrate 310 may be a semiconductor substrate that may include the detection elements. A detection element may be a diode. A detection element may also be an element similar to a diode that can convert incident energy into a measurable signal. The detection elements may comprise, for example, a PIN diode, an avalanche diode, an electron multiplier tube (EMT), etc., or combinations thereof. Additionally, the term “detection element” may include or cover “sensing element,” “sensor element,” “detection cell,” or “detector segment,” etc. In some embodiments, a pixel on the detector can be a detection element.

An area 325 may be provided between adjacent detection elements. Area 325 may be an isolation area to isolate the sides or corners of neighboring detection elements from one another. Area 325 may comprise an insulating material that is a material different from that of other areas of the detection surface of detector 300. Area 325 may be provided as a cross-shaped area as seen in the plane view of FIG. 3A. Area 325 may be provided as a square. In some embodiments, area 325 may not be provided between adjacent sides of detection elements. For example, in some embodiments, there may be no isolation area provided on a detection surface of a detector.

Detection elements may generate an electric signal commensurate with charged particles received in the active area of a detection element. For example, a detection element may generate an electric current signal commensurate with the energy of a received electron. A pre-processing circuit may convert the generated current signal into a voltage that may represent the intensity of an electron beam spot or a part thereof. The pre-processing circuitry may comprise, for example, pre-amp circuitries. Pre-amp circuitries may include, for example, a charge transfer amplifier (CTA), a transimpedance amplifier (TIA), or an impedance conversion circuit coupled with a CTA or a TIA. In some embodiments, signal processing circuitry may be provided that provides an output signal in arbitrary units on a timewise basis. There may be provided one or a plurality of substrates, such as dies, that may form circuit layers for processing the output of detection elements. The dies may be stacked together in a thickness direction of the detector. Other circuitries may also be provided for other functions. For example, switch actuating circuitries may be provided that may control switching elements for connecting detection elements to one another.

Reference is now made to FIG. 3B, which shows a schematic illustration of a cross-sectional structure of a substrate 310, which may be an example of a structure included in a PIN detector, consistent with embodiments of the present disclosure. Substrate 310 may comprise one or more layers. For example, substrate 310 may be configured to have a plurality of layers stacked in a thickness direction, the thickness direction being substantially parallel to an incidence direction of an electron beam. In some embodiments, substrate 310 may have a plurality of layers stacked in a direction perpendicular to the incidence direction of an electron beam. Substrate 310 may be provided with a sensor surface 301 for receiving incident charged particles. Detection elements (for example detection elements 311, 312, and 313) may be provided in a sensing layer of substrate 310. Area 325 may be provided between adjacent detection elements. For example, substrate 310 may comprise a trench, or other structure that is made of or filled with insulating material. In some embodiments, area 325 may extend fully or partially through substrate 310.

As shown in FIG. 3C, in some embodiments, area 325 may not be provided between detection elements, consistent with embodiments of the present disclosure. For example, there may be no insulating material provided between the sides of adjacent detection elements in cross-sectional view. The plurality of detection elements may be contiguous in cross-sectional view. Isolation between adjacent detection elements may still be achieved by other means, such as by controlling electrical field. For example, electrical field may be controlled between each detection element.

Although the figures may show detection elements 311, 312, and 313 as discrete units, such divisions may not actually be present. For example, the detection elements of a detector may be formed by a semiconductor device constituting a PIN diode device. The PIN diode device may be manufactured as a substrate with a plurality of layers including a p-type region, an intrinsic region, and an n-type region. One or more of such layers may be contiguous in cross-sectional view. In some embodiments, however, detection elements may be provided with physical separation between them. Further layers may also be provided in addition to the sensor layer, such as a circuit layer, and a read-out layer, for example.

As one example of a further layer, detector 300 may be provided with one or more circuit layers adjacent to the sensor layer. The one or more circuit layers may comprise line wires, interconnects, and various electronic circuit components. The one or more circuit layers may comprise a processing system. The one or more circuit layers may comprise signal processing circuitries. The one or more circuit layers may be configured to receive the output current detected from detection elements in the sensor layer. The one or more circuit layers and the sensor layer may be provided in the same or separate dies, for example.

FIG. 3D shows a schematic illustration of an individual detection element, which may be an example of one of detection elements 311, 312, and 313, consistent with embodiments of the present disclosure. For example, in FIG. 3D, a detection element 311A is shown. Detection element 311A may include a semiconductor structure of a p-type layer 321, an intrinsic layer 322, and an n-type layer 323. Detection element 311A may include two terminals, such as an anode and a cathode. Detection element 311A may be reverse biased, and a depletion region 330 may form and may span part of the length of p-type layer 321, substantially the entire length of intrinsic layer 322, and part of the length of n-type layer 323. In depletion region 330, charge carriers may be removed, and new charge carriers generated in depletion region 330 may be swept away according to their charge. For example, when an incoming charged particle reaches sensor surface 301, electron-hole pairs may be created, and a hole 351 may be attracted toward p-type layer 321 while an electron 352 may be attracted toward n-type layer 323. In some embodiments, a protection layer may be provided on sensor surface 301.

In operation, a depletion region of a detection element may function as a capture region. An incoming charged particle may interact with the semiconductor material in the depletion region and generate new charges. For example, the detection element may be configured such that a charged particle having a certain amount of energy or greater may cause electrons of the lattice of the semiconductor material to be dislodged, thus creating electron-hole pairs. The resulting electrons and holes may be caused to travel in opposite directions due to, for example, an electric field in the depletion region. Generation of carriers that travel toward terminals of the detection element may correspond to current flow in the detection element.

In a comparative example, a photodiode may be configured to generate electric charge in response to receiving photons. A photon may have energy that corresponds to its wavelength or frequency. Typically, a photon in the visible light spectrum may have energy on the order of about 1 eV. However, in a semiconductor photodiode, it is typical that about 3.6 eV may be required to generate one electron-hole pair. Therefore, photodiodes may encounter difficulties in detecting current generation such as the following.

In general, a level of energy of a photon may be similar to that required to generate an electron-hole pair in a semiconductor photodiode. Thus, in order to generate electric current stably and reliably, it may be necessary that photons of high energy be incident on a semiconductor photodiode. A photon may have energy sufficient to generate one electron-hole pair when its frequency is at or above a certain level.

Furthermore, the electric current generated by electron-hole pairs in response to photon arrival events may be relatively low. Current generated in response to photon arrival events may not be sufficient to overcome background noise. Some diodes, such as a photodiode biased to avalanche or Geiger counting mode, may employ amplification to generate a larger level of electric current so that a useful detection signal can be generated. In some embodiments, a photodiode may be biased to avalanche operation mode. In some embodiments, amplification may be provided by gain blocks attached to the photodiode. An avalanche effect may be generated from strong internal electric fields resulting from bias voltage. The avalanche effect may be used to achieve amplification due to impact ionization.

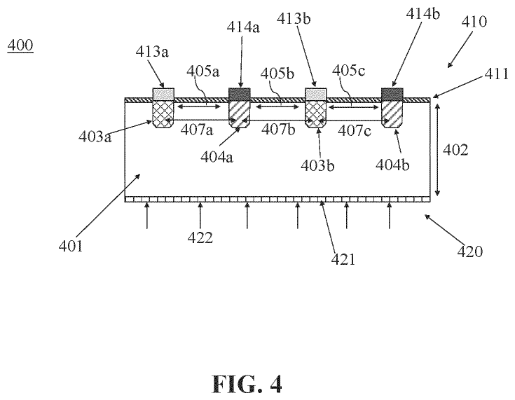

FIG. 4 shows a schematic illustration of an individual detection element, which may be an example of one of detection elements 311, 312, and 313, consistent with embodiments of the present disclosure. For example, in FIG. 4, a detection element 400 is shown. Detection element 400 may include a substrate (e.g., silicon substrate) 401 with lateral PIN diodes, where a first PIN diode includes an n-type region 403a (e.g., n-type dopants), a p-type region 404a (e.g., p-type dopants), and an intrinsic region 405a; a second PIN diode includes an n-type region 403b, p-type region 404a, and an intrinsic region 405b; and a third PIN diode includes n-type region 403b, a p-type region 404b, and an intrinsic region 405c. While three PIN diodes are shown, it should be understood that detection element 400 may include any number of PIN diodes. The PIN diodes may be formed on a front side 410 of detection element 400. In some embodiments, a passivation layer 411 may be formed on front side 410.

Detection element 400 may include terminals, such as a cathode 413a on n-type region 403a, an anode 414a on p-type region 404a, a cathode 413b on n-type region 403b, and an anode 414b on p-type region 404b. A region between n-type region 403a and p-type region 404a may form a depletion region 407a when a reverse bias is applied between n-type region 403a and p-type region 404a. Depletion region 407a may span part of the length of n-type region 403a, substantially the entire length of intrinsic region 405a, and part of the length p-type region 404a. In depletion region 407a, charge carriers may be removed, and new charge carriers generated in depletion region 407a may be swept away according to their charge. For example, when an incoming charged particle (e.g., an electron) reaches front side 410, electron-hole pairs may be created, and a hole may be attracted toward p-type region 404a while an electron may be attracted toward n-type region 403a. Similarly, a depletion region 407b may form between n-type region 403b and p-type region 404a and a depletion region 407c may form between n-type region 403b and p-type region 404b.

In operation, a depletion region of detection element 400 may function as a capture region. An incoming charged particle may interact with the semiconductor material in the depletion region and generate new charges. For example, detection element 400 may be configured such that a charged particle having a certain amount of energy or greater may cause electrons of the lattice of the semiconductor material to be dislodged, thus creating electron-hole pairs. The resulting electrons and holes may be caused to travel in opposite directions due to, for example, an electric field in the depletion region. Generation of carriers that travel toward terminals of detection element 400 may correspond to current flow in detection element 400.

In some embodiments, a passivation layer 421 may be formed on a back side 420 of substrate 401, opposite to front side 410. Unlike front side 410, which includes n-type regions 403a-b and p-type regions 404a-b, back side 420 may include a substantially uniform surface (e.g., a surface without implanted dopants, a material with an implanted dopant concentration of zero, zero PIN diodes, zero cathodes, zero anodes, etc.). The substantially uniform surface of back side 420 may be between front side 410 and passivation layer 421.

Substrate 401 may include a dopant concentration greater than zero, where the dopants are non-implanted dopants. The non-implanted dopants may be added to the silicon substrate as the silicon substrate is formed. For example, the dopant may be added to melted silicon and become part of the silicon substrate as the silicon crystal is grown to form the silicon substrate.

To detect particles, the PIN diode of detection element 400 may be configured to detect particles 422 (e.g., charged particles) that enter back side 420 and pass through silicon substrate 401 to a depletion region. In some embodiments, passivation layer 421 may include a material that is substantially transparent to electrons (e.g., SiN, thin metal, etc.) so that particles 422 (electrons) may pass through detection element 400 from back side 420 and the PIN diode of detection element 400 may detect the electrons. Therefore, passivation layer 421 would not include materials such as SiO₂, which is not transparent to electrons, when detection element 400 is used to detect electrons.

Advantageously, detection element 400 may use a lateral PIN diode by back side illumination to detect particles (e.g., the back side of the substrate may be exposed to secondary electrons while the front side of the substrate may not be exposed to secondary electrons), thereby increasing the responsivity, response speed, and fill factor of detection element 400. Detection responsivity may be described as a ratio of output to input (e.g., output current to input current) of a detection element. Detection response speed may be described as a time in which an electrical signal is generated by a detection element when a particle lands on the detection element. Detection fill factor may be described as a percentage of detection elements in an area of the detector that generate a signal.

The back side illumination detection of detection element 400 may exhibit increased responsivity and response speed during detection by avoiding carrier losses that would typically occur from front side illumination detection, such as carrier losses due a front side surface protection layer, front side heavily doped regions, surface metal layers, or electrical contacts on the front side of the PIN diode. For example, carrier losses may occur due to surface metal layers or electrical contacts on the front side of the PIN diode absorbed some electrons.

Advantageously, detection element 400 may use a thin substrate, thereby allowing the PIN diode on front side 410 to detect particles 422 that enter back side 420. For example, a thickness 402 of substrate 402 may be less than 20 μm or less than 30 μm so that particles 422 may reach front side 410 with high responsivity and high response speed. Thin substrate 402 also avoids the use of trenches and additional implants in detection element 400, which would typically be needed for back side illumination detection using a thick substrate.

Because substrate 401 is thin (e.g., less than 20 μm or less than 30 μm), depletion regions 407a-c may include back side 420 such that the entirety of substrate 401 is depleted. Advantageously, fully depleted substrate 401 may result in high responsivity and high response speed of detection element 400.

In some embodiments, the thickness of substrate 402 may be adjusted or controlled to control the detection response speed of detection element 400. In some embodiments, the detection responsivity, response speed, fill factor, and parasitics of detection element 400 may be adjusted or controlled by adjusting the PIN diodes, such as the widths of n-type regions 403a-b and p-type regions 404a-b, dopant concentrations of n-type regions 403a-b and p-type regions 404a-b, width of intrinsic regions 405a-c, etc.

Some typical detection elements may use a substrate with a thickness greater than 30 μm, which suffer from constraints. For example, detection elements with a substrate thickness greater than 30 μm may exhibit low responsivity and low response speed due to particles failing to reach the front side of the detection element or reaching the front side of the detection element slowly. Detection elements with a substrate thickness greater than 30 μm may also require more complex manufacturing due to the need for additional trenches and implants for particles to reach the front side of the detection element with high responsivity and high response speed. Embodiments of the present disclosure overcome these constraints by using a substrate with a thickness of less than 20 μm or less than 30 μm.

Some detection elements may also include implanted dopants on the back side of the detection element (i.e., implanted dopants on the side of the detection element where particles enter, implanted dopants on both the front side and the back side, etc.), which suffer from constraints. For example, detection elements with implanted dopants on the back side of the detection element may exhibit low responsivity and low response speed due to carrier losses in the back side the detection element. For example, carrier losses may occur due to the implanted dopants on the back side of the detection element absorbing some electrons. Embodiments of the present disclosure overcome these constraints by using a back side with a substantially uniform surface (e.g., a surface without implanted dopants, a material with an implanted dopant concentration of zero, zero PIN diodes, zero cathodes, zero anodes, etc.).

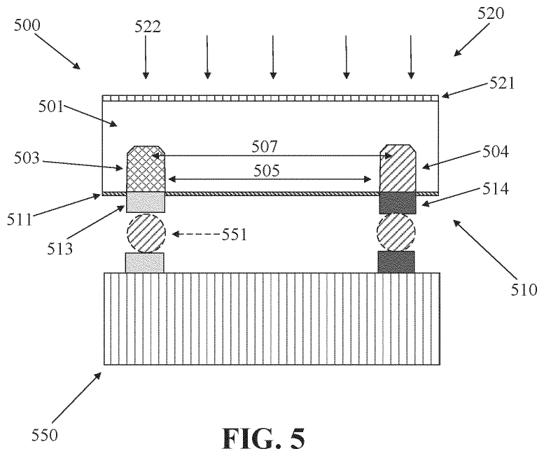

FIG. 5 shows a schematic illustration of an individual detection element, which may be an example of one of detection elements 311, 312, 313, and 400, and a readout integrated circuit, consistent with embodiments of the present disclosure.

As shown in FIG. 5, a detection element 500 may include a substrate (e.g., silicon substrate) 501 (e.g., substrate 401 of FIG. 4) with a lateral PIN diode, where the PIN diode includes an n-type region 503 (e.g., n-type dopants) (e.g., n-type regions 403a-b of FIG. 4), a p-type region 504 (e.g., p-type dopants) (e.g., p-type regions 404a-b of FIG. 4), and an intrinsic region 505 (e.g., intrinsic regions 405a-c of FIG. 4). The PIN diode may be formed on a front side 510 (e.g., front side 410 of FIG. 4) of detection element 500. In some embodiments, a passivation layer 511 (e.g., passivation layer 411 of FIG. 4) may be formed on front side 510.

Detection element 500 may include terminals, such as a cathode 513 (e.g., cathodes 413a-b of FIG. 4) on n-type region 503 and an anode 514 (e.g., anodes 414a-b of FIG. 4) on p-type region 504. A region between n-type region 503 and p-type region 504 may form a depletion region 507 (e.g., depletion regions 407a-c of FIG. 4) when a reverse bias is applied between n-type region 503 and p-type region 504. Depletion region 507 may span part of the length of n-type region 503, substantially the entire length of intrinsic region 505, and part of the length p-type region 504. Because substrate 501 is thin (e.g., less than 20 μm or less than 30 μm), depletion region 507 may include back side 520 such that the entirety of substrate 501 is depleted. Advantageously, fully depleted substrate 501 may result in high responsivity and high response speed of detection element 500.

In some embodiments, a passivation layer 521 (e.g., passivation layer 421 of FIG. 4) may be formed on a back side 520 (e.g., back side 420 of FIG. 4) of substrate 501, opposite to front side 510. Unlike front side 510, which includes n-type region 503 and p-type region 504, back side 520 may include a substantially uniform surface (e.g., a surface without implanted dopants, a material with an implanted dopant concentration of zero, zero PIN diodes, zero cathodes, zero anodes, etc.). To detect particles, the PIN diode of detection element 500 may be configured to detect particles 522 (e.g., charged particles) (e.g., particles 422 of FIG. 4) that enter back side 520 and pass through silicon substrate 501 to depletion region 507. In some embodiments, passivation layer 521 may include a material substantially transparent to electrons (e.g., SiN, thin metal, etc.) so that particles 522 (electrons) may pass through detection element 500 from back side 520 and the PIN diode of detection element 500 may detect the electrons. Therefore, passivation layer 521 would not include materials such as SiO₂, which is not transparent to electrons, when detection element 500 is used to detect electrons.

As shown in FIG. 5, since cathode 513 and anode 514 are on a same front side 510, detection element 500 may be easily and directly integrated to a readout integrated circuit 520 (e.g., CMOS ASIC) without using through-wafer vias in substrate 501. For example, detection element 500 may be bonded to readout integrated circuit 550 using bonding material 551 (e.g., solder bumps).

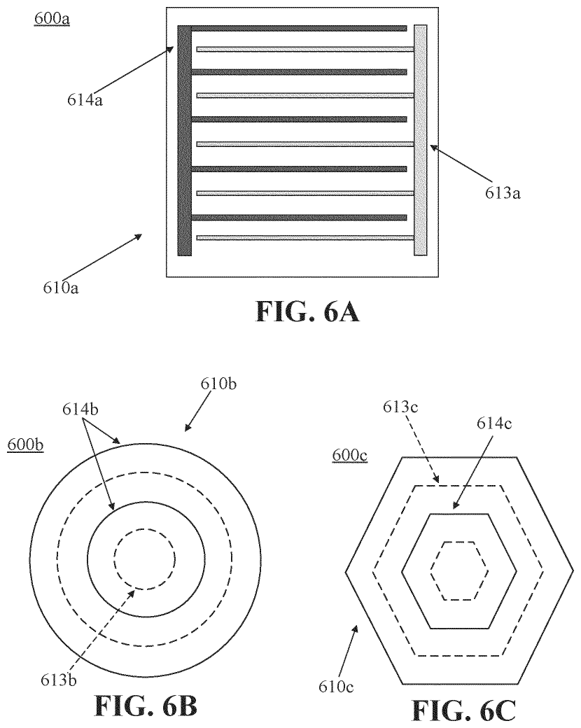

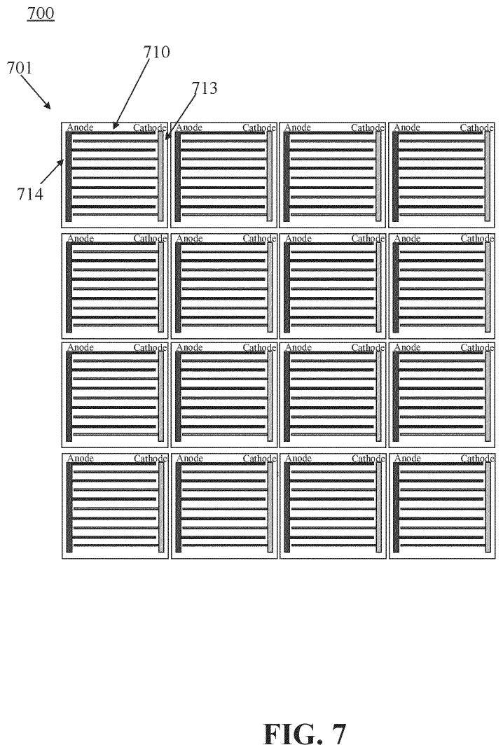

FIGS. 6A, 6B, and 6C show schematic illustrations of metal geometries of an individual detection element, which may be an example of one of detection elements 311, 312, 313, 400, and 500, consistent with embodiments of the present disclosure.

As shown in FIG. 6A, a detection element 600a (e.g., detection element 400 of FIG. 4, detection element 500 of FIG. 5) may include a cathode 613a (e.g., cathodes 413a-b of FIG. 4, cathode 513 of FIG. 5) and an anode 614a (e.g., anodes 414a-b of FIG. 4, anode 514 of FIG. 5) on its front side 610a (e.g., front side 410 of FIG. 4, front side 510 of FIG. 5). In some embodiments, cathode 613a and anode 614a of detection element 600a may be arranged to interdigitate. In some embodiments, the metal geometry of interdigitated detection element 600a may be adjusted to control or adjust detection responsivity, response speed, parasitics, or losses from front side 610a.

As shown in FIG. 6B, a detection element 600b (e.g., detection element 400 of FIG. 4, detection element 500 of FIG. 5) may include a cathode 613b (e.g., cathodes 413a-b of FIG. 4, cathode 513 of FIG. 5) and an anode 614b (e.g., anodes 414a-b of FIG. 4, anode 514 of FIG. 5) on its front side 610b (e.g., front side 410 of FIG. 4, front side 510 of FIG. 5). In some embodiments, cathode 613b and anode 614b of detection element 600b may be concentrically arranged in a circular shape. In some embodiments, the metal geometry of detection element 600b may be adjusted to control or adjust detection responsivity, response speed, parasitics, or losses from front side 610b.

As shown in FIG. 6C, a detection element 600c (e.g., detection element 400 of FIG. 4, detection element 500 of FIG. 5) may include a cathode 613c (e.g., cathodes 413a-b of FIG. 4, cathode 513 of FIG. 5) and an anode 614c (e.g., anodes 414a-b of FIG. 4, anode 514 of FIG. 5) on its front side 610c (e.g., front side 410 of FIG. 4, front side 510 of FIG. 5). In some embodiments, cathode 613c and anode 614c of detection element 600c may be concentrically arranged in a hexagonal shape. In some embodiments, the metal geometry of detection element 600c may be adjusted to control or adjust detection responsivity, response speed, parasitics, or losses from front side 610c. In some embodiments, the metal geometry of detection element 600c may be used to reduce the breakdown voltage of detection element 600c.

In some embodiments, the metal geometries of detection elements 600a, 600b, and 600c may improve the uniformity and consistency of detection responsivity, response speed, and fill factor across the detector.

Reference is now made to FIG. 7, which illustrates a schematic illustration of an exemplary structure of a detector 700 (e.g., detector 300 of FIG. 3), consistent with embodiments of the present disclosure. Detector 700 may be provided as detector 144 or electron detection device 240 with reference to FIG. 2A and FIG. 2B. While one array is shown in FIG. 7, it is appreciated that detector 700 may include multiple arrays, such as one array for each secondary electron beam.

Detector 700 may include an array of detection elements, including detection elements 701 (e.g., 311, 312, 313, 400, 500, 600a, 600b, 600c). The detection elements may be arranged in a planar, two-dimensional array, the plane of the array being substantially perpendicular to an incidence direction of incoming charged particles. In some embodiments, detector 700 may be arranged so as to be inclined relative to the incidence direction. The PIN diodes of the detection elements may be positioned in a lateral geometry to provide a larger density of PIN diodes per unit area. For example, the array may include any combination of any number of a p-type and n-type regions in alternating order.

As shown in FIG. 7, detection element 701 may include a cathode 713 (e.g., cathodes 413a-b of FIG. 4, cathode 513 of FIG. 5) and an anode 714 (e.g., anodes 414a-b of FIG. 4, anode 514 FIG. 5) on its front side 710 (e.g., front side 410 of FIG. 4, front side 510 of FIG. 5). While cathode 713 and anode 714 are arranged to interdigitate (e.g., detection element 600a of FIG. 6A), it should be understood that the metal geometry of detection element 701 is not limited and that other metal geometries (e.g., detection element 600b of FIG. 6B, detection element 600c of FIG. 6C) may be used as well.

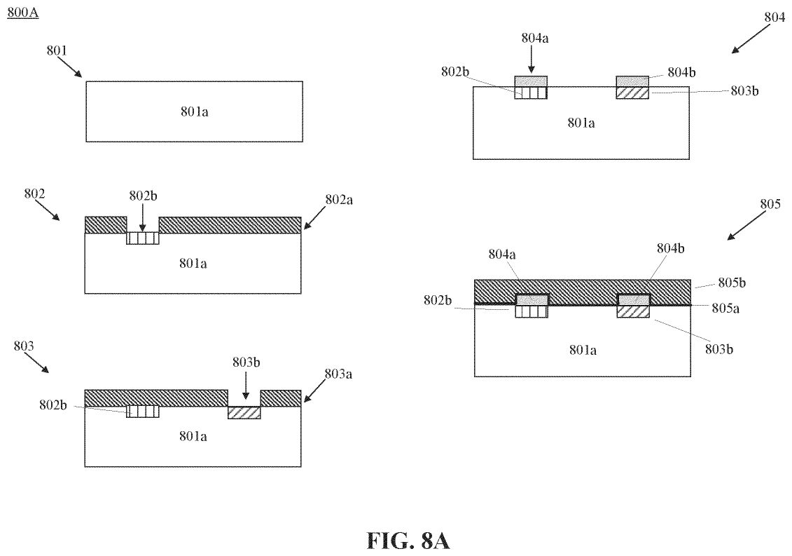

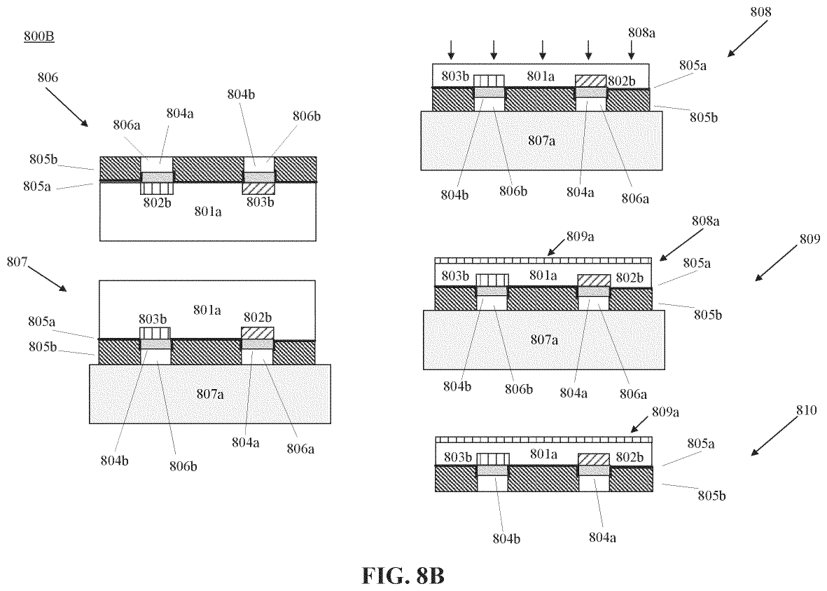

Reference is now made to FIGS. 8A and 8B, flowcharts illustrating exemplary processes 800A and 800B of forming a detection element (e.g., 311, 312, 313, 400, 500, 600a, 600b, 600c, 701), consistent with embodiments of the present disclosure. The steps of processes 800A and 800B can be performed by a system executing on or otherwise using the features of a computing device (e.g., controller 109 of FIG. 1, FIG. 2A, FIG. 2B, etc.) for purposes of illustration. It is appreciated that the illustrated processes 800A and 800B can be altered to modify the order of steps and to include additional steps.

For example, process 800A of FIG. 8A shows that at step 801, a substrate 801a (e.g., silicon, SOI, etc.) (e.g., substrate 401 of FIG. 4, substrate 501 of FIG. 5) may be prepared for processing. In some embodiments, substrate 801a may be a thick substrate (e.g., 500-600 μm) that forms an intrinsic region (e.g., intrinsic regions 405a-c of FIG. 4, intrinsic region 505 of FIG. 5) of a PIN diode.

At step 802, a layer 802a may be used to implant p-type dopants in substrate 801a to form a p-type region 802b (e.g., p-type regions 404a-b of FIG. 4, p-type region 504 of FIG. 5). In some embodiments, layer 802a (e.g., SiN, SiO₂, Diazonaphthoquinone-based resists (DNQ-Novolak), etc.) may be capable of blocking ions from entering areas of substrate 801a outside of p-type region 802b. In some embodiments, p-type region 802b may be adjusted to adjust the depletion region of the PIN diode. For example, p-type region 802b may be adjusted by adjusting its depth, width, or dopant concentration. In some embodiments, layer 802a may be a photoresist that is deposited and patterned. The photoresist may be deposited and patterned before the ion implantation and the photoresist may be removed after the ion implantation. In some embodiments, layer 802a may include an insulator and a photoresist. The insulator and the photoresist may be deposited and the photoresist may be patterned. Using the photoresist pattern, the insulator may be patterned using a selective etching process. The photoresist may be removed and the ion implantation may be performed. The insulator may then be removed.

At step 803, a layer 803a may be used to implant n-type dopants in substrate 801a to form an n-type region 803b (e.g., n-type regions 403a-b of FIG. 4, n-type region 503 of FIG. 5). In some embodiments, layer 803a (e.g., SiN, SiO₂, Diazonaphthoquinone-based resists (DNQ-Novolak), etc.) may be capable of blocking ions from entering areas of substrate 801a outside of n-type region 803b. In some embodiments, n-type region 803b may be adjusted to adjust the depletion region of the PIN diode. For example, n-type region 803b may be adjusted by adjusting its depth, width, or dopant concentration.

At step 804, a metal layer may be deposited and patterned on p-type region 802b to form an anode 804a and on n-type region 803b to form a cathode 804b. For example, the metal layer may be selectively deposited onto p-type region 802b and n-type region 803b through photolithography patterning using a sacrificial mask, followed by metal filling or metal deposition. In some embodiments, anode 804a and cathode 804b may be of an alloy or pure metal (e.g., aluminum (Al), tungsten (W), silicides (TiSi₂, MoSi₂, PtSi, CoSi₂, WSi₂), etc.).

At step 805, a first passivation layer 805a may be formed on anode 804a and cathode 804b and a second passivation layer 805b may be formed on first passivation layer 805a. In some embodiments, passivation layers 805a and 805b may act as insulators. In some embodiments, the thicknesses of passivation layers 805a and 805b may be adjusted. For example, passivation layer 805b (e.g., 5-10 μm) may be thicker than passivation layer 805a (e.g., 100 nm). In some embodiments, passivation layer 805a may be used to reduce the recombination losses from the surface of substrate 801a, which can be thin (e.g., less than 100 nm). In some embodiments, passivation layer 805b may be optionally included for mechanical support for the step of thinning substrate 801a (step 808), where thicker layers provide more support.

As shown in FIG. 8B in process 800B, at step 806, following step 805 of FIG. 8A, via holes 806a and 806b may be patterned in passivation layers 805a and 805b such that via holes 806a and 806b are aligned with anode 804a and cathode 804b, respectively, such that anode 804a and cathode 804b may be exposed from passivation layers 805a and 805b.

At step 807, carrier substrate 807a may be attached to passivation layer 805b in preparation for substrate thinning.

At step 808, a back side 808a of substrate 801a may be thinned such that a thickness of substrate 801a is reduced (e.g., reduced to a thickness of 20 μm, 30 μm, etc.) while carrier substrate 807a is attached to passivation layer 805b. In some embodiments, substrate 801a may be thinned through a process of chemically based etching (e.g., polishing via chemical-mechanical polishing (CMP), dry etching, etc.) or grinding. As discussed above, the thinned substrate allows the directionality of electrons to travel from the back of substrate 801a to the PIN diode without losing their energy or direction of path within the intrinsic region.

At step 809, a layer 809a (e.g., layer 421 of FIG. 4, layer 521 of FIG. 5) may be deposited on back side 808a of thinned substrate 801a. In some embodiments, layer 809a may protect substrate 801a and include a material substantially transparent to electrons (e.g., SiN, thin metal, etc.).

At step 810, carrier substrate 807a may be removed. In some embodiments, when passivation layer 805b is included for mechanical support to the substrate thinning step, passivation layer 805b may remain in the final detection element or may be removed.

The embodiments may further be described using the following clauses:
1. A detector comprising:
   a silicon substrate thinned to a thickness of 30 μm or less;
   a front side of the silicon substrate including a lateral PIN diode formed by a p-type implant and an n-type implant;
   a region between the p-type implant and the n-type implant configured to form a depletion region when a reverse bias is applied between the p-type implant and the n-type implant;
   a back side of the silicon substrate, opposite of the front side, comprising a substantially uniform surface; and
   a protective layer on the substantially uniform surface on the back side of the silicon substrate,
   wherein the lateral PIN diode is configured to detect an electron that enters the back side of the silicon substrate and passes through the silicon substrate to the depletion region.
2. The detector of clause 1, wherein the protective layer comprises a material substantially transparent to electrons.
3. The detector of any one of clauses 1-2, wherein the substantially uniform surface of the back side of the silicon substrate comprises an implanted dopant concentration of substantially zero.
4. The detector of clause 3, wherein the silicon substrate comprises a dopant concentration greater than zero, wherein the dopant of the dopant concentration is non-implanted dopant.
5. The detector of clause 4, wherein the non-implanted dopant is added to the silicon substrate as the silicon substrate is formed.
6. The detector of any one of clauses 1-5, wherein the substantially uniform surface of the back side of the silicon substrate is between the front side and the protective layer.
7. The detector of any one of clauses 1-6, wherein the back side of the silicon substrate comprises zero PIN diodes.
8. The detector of any one of clauses 1-7, wherein the back side of the silicon substrate comprises zero anodes and zero cathodes.
9. The detector of any one of clauses 1-8, wherein the back side of the silicon substrate is configured to be exposed to secondary electrons, while the front side of the silicon substrate is configured to not be exposed to secondary electrons.
10. The detector of any one of clauses 1-9, wherein the lateral PIN diode comprises an anode on the p-type implant and a cathode on the n-type implant.
11. The detector of clause 10, wherein the cathode and the anode are arranged to interdigitate.
12. The detector of clause 10, wherein the cathode and the anode are concentrically arranged in a circular shape.
13. The detector of clause 10, wherein the cathode and the anode are concentrically arranged in a hexagonal shape.
14. The detector of clause 10, wherein the lateral PIN diode is bonded, by the cathode and the anode, to a readout integrated circuit.
15. A detector comprising:
   a plurality of detection elements, a detection element of the plurality of detection elements comprising:
   a portion of a silicon substrate comprising:
      a front side of the portion of the silicon substrate including a PIN diode that comprises a p-type region and an n-type region;
      a back side of the portion of the silicon substrate, opposite of the front side, comprising a substantially uniform surface; and
      a layer on the back side of the portion of the silicon substrate;
   wherein:
      a region between the p-type region and the n-type region is configured to form a depletion region when a reverse bias is applied between the p-type region and the n-type region, and
      the PIN diode is configured to detect an electron that enters the back side of the portion of the silicon substrate and passes through the portion of the silicon substrate to the depletion region.
16. The detector of clause 15, wherein the layer comprises a material substantially transparent to electrons.
17. The detector of any one of clauses 15-16, wherein a thickness of the portion of the silicon substrate is 30 μm or less.
18. The detector of any one of clauses 15-17, wherein the substantially uniform surface of the back side of the portion of the silicon substrate comprises an implanted dopant concentration of substantially zero.
19. The detector of clause 18, wherein the portion of the silicon substrate comprises a dopant concentration greater than zero, wherein the dopant of the dopant concentration is non-implanted dopant.
20. The detector of clause 19, wherein the non-implanted dopant is added to the portion of the silicon substrate as the portion of the silicon substrate is formed.
21. The detector of any one of clauses 15-20, wherein the substantially uniform surface of the back side of the portion of the silicon substrate is between the front side and the layer.
22. The detector of any one of clauses 15-21, wherein the back side of the portion of the silicon substrate comprises zero PIN diodes.
23. The detector of any one of clauses 15-22, wherein the back side of the portion of the silicon substrate comprises zero anodes and zero cathodes.
24. The detector of any one of clauses 15-23, wherein the back side of the portion of the silicon substrate is configured to be exposed to secondary electrons, while the front side of the portion of the silicon substrate is configured to not be exposed to secondary electrons.
25. The detector of any one of clauses 15-24, wherein the PIN diode comprises an anode on the p-type region and a cathode on the n-type region.
26. The detector of clause 25, wherein the cathode and the anode are arranged to interdigitate.
27. The detector of clause 25, wherein the cathode and the anode are concentrically arranged in a circular shape.
28. The detector of clause 25, wherein the cathode and the anode are concentrically arranged in a hexagonal shape.
29. The detector of clause 25, wherein the PIN diode is bonded, by the cathode and the anode, to a readout integrated circuit.
30. A detector comprising a plurality of detection elements, a detection element of the plurality of detection elements comprising:
   a portion of a silicon substrate comprising:
      a front side of the portion of the substrate including a PIN diode that comprises a p-type region and an n-type region;
      a back side of the portion of the substrate, opposite of the front side, comprising a substantially uniform surface; and
      a layer on the back side of the portion of the substrate;
   wherein:
      a region between the p-type region and the n-type region is configured to form a depletion region when a reverse bias is applied between the p-type region and the n-type region, and
      the PIN diode is configured to receive an electron incident on the back side of the portion of the substrate.
31. The detector of clause 30, wherein the layer comprises a material substantially transparent to electrons.
32. The detector of any one of clauses 30-31, wherein a thickness of the portion of the substrate is 30 μm or less.
33. The detector of any one of clauses 30-32, wherein the substantially uniform surface of the back side of the portion of the substrate comprises an implanted dopant concentration of substantially zero.
34. The detector of clause 33, wherein the portion of the substrate comprises a dopant concentration greater than zero, wherein the dopant of the dopant concentration is non-implanted dopant.
35. The detector of clause 34, wherein the non-implanted dopant is added to the portion of the substrate as the portion of the substrate is formed.
36. The detector of any one of clauses 30-35, wherein the substantially uniform surface of the back side of the portion of the substrate is between the front side and the layer.
37. The detector of any one of clauses 30-36, wherein the back side of the portion of the substrate comprises zero PIN diodes.
38. The detector of any one of clauses 30-37, wherein the back side of the portion of the substrate comprises zero anodes and zero cathodes.
39. The detector of any one of clauses 30-38, wherein the back side of the portion of the substrate is configured to be exposed to secondary electrons, while the front side of the portion of the substrate is configured to not be exposed to secondary electrons.
40. The detector of any one of clauses 30-39, wherein the PIN diode comprises an anode on the p-type region and a cathode on the n-type region.
41. The detector of clause 40, wherein the cathode and the anode are arranged to interdigitate.
42. The detector of clause 40, wherein the cathode and the anode are concentrically arranged in a circular shape.
43. The detector of clause 40, wherein the cathode and the anode are concentrically arranged in a hexagonal shape.
44. The detector of clause 40, wherein the PIN diode is bonded, by the cathode and the anode, to a readout integrated circuit.
45. A detector comprising a plurality of detection elements, a detection element of the plurality of detection elements comprising:
   a portion of a substrate comprising:
      a front side of the portion of the substrate including a p-type region and an n-type region, the p-type region and the n-type region forming a PIN diode; and
      a back side of the portion of the substrate, opposite of the front side, comprising a substantially uniform surface;
   wherein:
      a region between the p-type region and the n-type region is configured to form a depletion region when a reverse bias is applied between the p-type region and the n-type region, and
      the PIN diode is configured to receive an electron passing from the back side of the portion of the substrate through the portion of the substrate.
46. The detector of clause 45, wherein a thickness of the portion of the substrate is 30 μm or less.
47. The detector of any one of clauses 45-46, wherein the substantially uniform surface of the back side of the portion of the substrate comprises an implanted dopant concentration of substantially zero.
48. The detector of clause 47, wherein the portion of the substrate comprises a dopant concentration greater than zero, wherein the dopant of the dopant concentration is non-implanted dopant.
49. The detector of clause 48, wherein the non-implanted dopant is added to the portion of the substrate as the portion of the substrate is formed.
50. The detector of any one of clauses 45-49, wherein the substantially uniform surface of the back side of the portion of the substrate is between the front side and the layer.
51. The detector of any one of clauses 45-50, wherein the back side of the portion of the substrate comprises zero PIN diodes.
52. The detector of any one of clauses 45-51, wherein the back side of the portion of the substrate comprises zero anodes and zero cathodes.
53. The detector of any one of clauses 45-52, wherein the back side of the portion of the substrate is configured to be exposed to secondary electrons, while the front side of the portion of the substrate is configured to not be exposed to secondary electrons.
54. The detector of any one of clauses 45-53, wherein the PIN diode comprises an anode on the p-type region and a cathode on the n-type region.
55. The detector of clause 54, wherein the cathode and the anode are arranged to interdigitate.
56. The detector of clause 54, wherein the cathode and the anode are concentrically arranged in a circular shape.
57. The detector of clause 54, wherein the cathode and the anode are concentrically arranged in a hexagonal shape.
58. The detector of clause 54, wherein the PIN diode is bonded, by the cathode and the anode, to a readout integrated circuit.
59. A method of forming a detection element of a detector, the method comprising:
   forming a PIN diode on a front side of a silicon substrate by implanting, in the silicon substrate, p-type dopants to form a p-type region and n-type dopants to form an n-type region,
   wherein a region between the p-type region and the n-type region is configured to form a depletion region when a reverse bias is applied between the p-type region and the n-type region;
   thinning a back side of the silicon substrate, opposite of the front side, wherein the back side comprises a substantially uniform surface; and
   forming a layer on the back side of the silicon substrate,
   wherein the PIN diode is configured to detect an electron that enters the back side of the silicon substrate and passes through the silicon substrate to the depletion region.
60. The method of clause 59, further comprising using a photoresist to implant the p-type dopants and the n-type dopants.
61. The method of clause 60, further comprising depositing and patterning a metal layer on the p-type region to form an anode and on the n-type region to form a cathode.
62. The method of clause 61, wherein the cathode and the anode are arranged to interdigitate.
63. The method of clause 61, wherein the cathode and the anode are concentrically arranged in a circular shape.
64. The method of clause 61, wherein the cathode and the anode are concentrically arranged in a hexagonal shape.
65. The method of any one of clauses 61-64, further comprising depositing a first passivation layer on the patterned metal layer and depositing a second passivation layer on the first passivation layer, the second passivation layer being thicker than the first passivation layer.
66. The method of clause 65, further comprising patterning via holes in the first passivation layer and the second passivation layer, wherein the via holes are aligned with the cathode and the anode.
67. The method of clause 66, further comprising attaching a carrier substrate to the second passivation layer.
68. The method of clause 67, wherein thinning the back side of the silicon substrate comprises reducing a thickness of the silicon substrate to 30 μm or less while the carrier substrate is attached to the second passivation layer.
69. The method of any one of clauses 67-68, wherein thinning the back side of the silicon substrate comprising grinding or dry etching the back side of the silicon substrate.
70. The method of any one of clauses 59-69, further comprising depositing the layer on the back side of the silicon substrate after thinning the back side of the silicon substrate.
71. The method of any one of clauses 59-70, wherein the layer comprises a material transparent to electrons.
72. The method of any one of clauses 67-71, further comprising removing the carrier substrate.
73. The method of any one of clauses 59-72, wherein the substantially uniform surface of the back side of the substrate comprises an implant concentration of zero.
74. The method of any one of clauses 72-73, further comprising bonding the PIN diode, by the cathode and the anode, to a readout integrated circuit.
75. A detector formed by any one of clauses 59-74, the detector comprising:
   a plurality of detection elements, a detection element of the plurality of detection elements comprising:
   a portion of a silicon substrate comprising:
      a front side of the portion of the silicon substrate including a PIN diode that comprises a p-type region and an n-type region;
      a back side of the portion of the silicon substrate, opposite of the front side, comprising a substantially uniform surface; and
      a layer on the back side of the portion of the silicon substrate;
   wherein:
      a region between the p-type region and the n-type region is configured to form a depletion region when a reverse bias is applied between the p-type region and the n-type region, and
      the PIN diode is configured to detect an electron that enters the back side of the portion of the silicon substrate and passes through the silicon substrate to the depletion region.

It will be appreciated that the embodiments of the present disclosure are not limited to the exact construction that has been described above and illustrated in the accompanying drawings, and that various modifications and changes may be made without departing from the scope thereof.

1. A detector comprising:
a plurality of detection elements, a detection element of the plurality of detection elements comprising:
a portion of a silicon substrate comprising:
a front side of the portion of the silicon substrate including a PIN diode that comprises a p-type region and an n-type region;
a back side of the portion of the silicon substrate, opposite of the front side, comprising a substantially uniform surface; and
a layer on the back side of the portion of the silicon substrate;
wherein:
a region between the p-type region and the n-type region is configured to form a depletion region when a reverse bias is applied between the p-type region and the n-type region, and
the PIN diode is configured to detect an electron that enters the back side of the portion of the silicon substrate and passes through the portion of the silicon substrate to the depletion region.

2. The detector of claim 1, wherein the layer comprises a material substantially transparent to electrons.

3. The detector of claim 1, wherein a thickness of the portion of the silicon substrate is 30 μm or less.

4. The detector of claim 1, wherein the substantially uniform surface of the back side of the portion of the silicon substrate comprises an implanted dopant concentration of substantially zero.

5. The detector of claim 4, wherein the portion of the silicon substrate comprises a dopant concentration greater than zero, wherein the dopant of the dopant concentration is non-implanted dopant.

6. The detector of claim 5, wherein the non-implanted dopant is added to the portion of the silicon substrate as the portion of the silicon substrate is formed.

7. The detector of claim 1, wherein the substantially uniform surface of the back side of the portion of the silicon substrate is between the front side and the layer.

8. The detector of claim 1, wherein the back side of the portion of the silicon substrate comprises zero PIN diodes.

9. The detector of claim 1, wherein the back side of the portion of the silicon substrate comprises zero anodes and zero cathodes.

10. The detector of claim 1, wherein the back side of the portion of the silicon substrate is configured to be exposed to secondary electrons, while the front side of the portion of the silicon substrate is configured to not be exposed to secondary electrons.

11. The detector of claim 1, wherein the PIN diode comprises an anode on the p-type region and a cathode on the n-type region.

12. The detector of claim 11, wherein the cathode and the anode are arranged to interdigitate.

13. The detector of claim 11, wherein the cathode and the anode are concentrically arranged in a circular shape.

14. The detector of claim 11, wherein the cathode and the anode are concentrically arranged in a hexagonal shape.

15. A method of forming a detection element of a detector, the method comprising:
forming a PIN diode on a front side of a silicon substrate by implanting, in the silicon substrate, p-type dopants to form a p-type region and n-type dopants to form an n-type region,
wherein a region between the p-type region and the n-type region is configured to form a depletion region when a reverse bias is applied between the p-type region and the n-type region;
thinning a back side of the silicon substrate, opposite of the front side, wherein the back side comprises a substantially uniform surface; and
forming a layer on the back side of the silicon substrate,
wherein the PIN diode is configured to detect an electron that enters the back side of the silicon substrate and passes through the silicon substrate to the depletion region.

16. A detector comprising:
a silicon substrate thinned to a thickness of 30 μm or less;
a front side of the silicon substrate including a lateral PIN diode formed by a p-type implant and an n-type implant;
a region between the p-type implant and the n-type implant configured to form a depletion region when a reverse bias is applied between the p-type implant and the n-type implant;
a back side of the silicon substrate, opposite of the front side, comprising a substantially uniform surface; and
a protective layer on the substantially uniform surface on the back side of the silicon substrate,
wherein the lateral PIN diode is configured to detect an electron that enters the back side of the silicon substrate and passes through the silicon substrate to the depletion region.

17. The detector of claim 16, wherein the protective layer comprises a material substantially transparent to electrons.

18. The detector of claim 16, wherein the substantially uniform surface of the back side of the silicon substrate comprises an implanted dopant concentration of substantially zero.

19. The detector of claim 16, wherein the silicon substrate comprises a dopant concentration greater than zero, and wherein the dopant of the dopant concentration is non-implanted dopant.

20. The detector of claim 19, wherein the non-implanted dopant is added to the silicon substrate as the silicon substrate is formed.
